(19) United States
(12) Patent Application Publication
(10) Pub. No.: US 2025/0107226 A1
(43) Pub. Date: Mar. 27, 2025

(54) TERNARY CMOS DEVICE

(71) Applicant: UIF (University Industry Foundation), Yonsei University, Seoul (KR)

(72) Inventors: Jiwon Chang, Seoul (KR); Sekwon Hong, Seoul (KR); Changwook Lee, Seoul (KR); Jae Eun Seo, Hwaseong-si (KR)

(21) Appl. No.: 18/895,073

(22) Filed: Sep. 24, 2024

(30) Foreign Application Priority Data
Sep. 27, 2023 (KR) 10-2023-0129902

(51) Int. Cl. H10N 70/00; H01L 27/092

(52) U.S. Cl. CPC H10D 84/85

(57) ABSTRACT

Disclosed is a ternary CMOS device including a two-dimensional material layer formed of a two-dimensional material, an n-type MOSFET region stacked on a top of the two-dimensional material layer, and a p-type MOSFET region stacked on the top of the two-dimensional material layer, wherein the two-dimensional material layer includes a two-dimensional phase change material layer formed of a two-dimensional phase change material, an n-channel two-dimensional semiconductor material layer stacked on a bottom of the n-type MOSFET region and connected to one end of the two-dimensional phase change material layer, and a p-channel two-dimensional semiconductor material layer stacked on a bottom of the p-type MOSFET region and connected to the other end of the two-dimensional phase change material layer.

### CROSS-REFERENCE TO RELATED APPLICATIONS

This application claims priority under 35 U.S.C. § 119 to Korean Patent Application No. 10-2023-0129902 filed on Sep. 27, 2023, in the Korean Intellectual Property Office, the disclosures of which are incorporated by reference herein in their entireties.

### BACKGROUND

The embodiment of the present invention relates to a CMOS device that enables ternary operation.

The present disclosure is derived from a basic personal study (Project Identification Number: 1711181765, Project Number: 2022R1A2C2008726, Research Project Name: Research on Ternary CMOS technology capable of monolithic 3D integration using phase transition according to the thickness of 2D materials to implement logic-in-memory, Project Management Agency: National Research Foundation of Korea, Research Period: from Mar. 1, 2023 to Feb. 29, 2024) conducted by the Ministry of Science and ICT. On the other hand, there is no property interest of the Korean government in any aspect of the present disclosure.

A CMOS (Complementary Metal-Oxide Semiconductor) is a type of integrated circuit and is widely used in the circuits of most electronic devices. The CMOS is a device in which a p-channel MOSFET (p-MOS) and an n-channel MOSFET (n-MOS) are formed on a single chip, with the p-channel MOS and the n-channel MOS operating in a complementary manner. The CMOS is mainly used to configure integrated circuits such as microprocessors, SRAM (Static Random Access Memory), and image sensors. The CMOS is widely used because the CMOS is cheaper than a process using a BJT device and is able to implement low-power circuits.

In recent years, semiconductor device technology has been actively researched to address the question of how much power consumption can be reduced. However, there is a fundamental problem in that it is difficult to solve the power consumption problem in large-scale information processing such as big data using binary elements that express information in the binary notation of 0 and 1.

### SUMMARY

Embodiments of the present disclosure provide a ternary CMOS device capable of performing ternary operations.

In addition, embodiments of the present disclosure provide a ternary CMOS device based on a two-dimensional material that is available for various purposes from an ultra-low power environment to a high-performance environment by supporting a wide range of operating speeds.

In addition, embodiments of the present disclosure provide a ternary CMOS device capable of being implemented more robustly and stably because there is no process dispersion due to doping.

In addition, embodiments of the present disclosure provide a ternary CMOS device capable of using a semiconductor material capable of enabling top integration under process conditions that do not deteriorate the characteristics and reliability of Si-based CMOS to increase the integration density of a device.

Meanwhile, the technical problems to be solved by the inventive concept are not limited to the aforementioned problems, and any other technical problems not mentioned herein will be clearly understood from the following description by those skilled in the art to which the inventive concept pertains.

According to an embodiment, a ternary CMOS device includes a two-dimensional material layer formed of a two-dimensional material, an n-type MOSFET region stacked on a top of the two-dimensional material layer, and a p-type MOSFET region stacked on the top of the two-dimensional material layer, and the two-dimensional material layer includes a two-dimensional phase change material layer formed of a two-dimensional phase change material, an n-channel two-dimensional semiconductor material layer stacked on a bottom of the n-type MOSFET region and connected to one end of the two-dimensional phase change material layer; and a p-channel two-dimensional semiconductor material layer stacked on a bottom of the p-type MOSFET region and connected to the other end of the two-dimensional phase change material layer.

The n-channel two-dimensional semiconductor material layer may be formed of a two-dimensional semiconductor material having a characteristic of changing into an n-type conductor by a voltage change without separate doping, and the p-channel two-dimensional semiconductor material layer may be formed of a two-dimensional semiconductor material having a characteristic of changing into a p-type conductor by a voltage change without separate doping.

The two-dimensional phase change material layer may be formed of a two-dimensional phase change material having a decreasing band gap as a thickness of the layer increases.

The two-dimensional phase change material layer may be formed of transition metal dichalcogenides (TMDs) having a decreasing band gap as the thickness of the layer increases.

The two-dimensional phase change material layer may be formed of at least one of PtSe2 (Platinum Diselenide) and PdSe2 (Palladium Diselenide).

The two-dimensional phase change material layer may be formed of at least one of arsenene which is a two-dimensional phase change material composed of single atoms, is an allotrope of arsenic (As) and has a two-dimensional structure, and antimonene which is a two-dimensional phase change material composed of single atoms, is an allotrope of antimony (Sb) and has a two-dimensional structure.

The n-type MOSFET region may include a first source terminal stacked on a top of the n-channel two-dimensional semiconductor material layer, a first gate terminal stacked on the top of the n-channel two-dimensional semiconductor material layer to receive an input voltage, and a common drain terminal stacked on a top of the two-dimensional phase change material layer, and the p-type MOSFET region may include a second source terminal stacked on a top of the p-channel two-dimensional semiconductor material layer, a second gate terminal stacked on the top of the p-channel two-dimensional semiconductor material layer to receive the input voltage, and the common drain terminal.

The two-dimensional material layer may act as a resistor to limit an on current flowing via the n-type MOSFET region, the n-channel two-dimensional semiconductor material layer, the p-type MOSFET region, and the p-channel two-dimensional semiconductor material layer.

The n-type MOSFET region may further include a first oxide material layer stacked on the top of the n-channel two-dimensional semiconductor material layer and a bottom of the first gate terminal to be positioned between the n-channel two-dimensional semiconductor material layer and the first gate terminal, and the p-type MOSFET region may further include a second oxide material layer stacked on the top of the p-channel two-dimensional semiconductor material layer and a bottom of the second gate terminal to be positioned between the p-channel two-dimensional semiconductor material layer and the second gate terminal.

The ternary CMOS device may further include a first spacer formed of an insulating material and stacked on the top of the n-channel two-dimensional semiconductor material layer and arranged between the first gate terminal and the first source terminal and between the first oxide material layer and the first source terminal, a second spacer formed of an insulating material and stacked on the top of the two-dimensional phase change material layer and arranged between the first gate terminal and the common drain terminal and between the first oxide material layer and the common drain terminal, a third spacer formed of an insulating material and stacked on the top of the two-dimensional phase change material layer and arranged between the second gate terminal and the common drain terminal and between the second oxide material layer and the common drain terminal, and a fourth spacer formed of an insulating material and stacked on the top of the p-channel two-dimensional semiconductor material layer and arranged between the second gate terminal and the second source terminal and between the second oxide material layer and the second source terminal.

The ternary CMOS device may further include a CMOS input terminal connected to the first gate terminal and the second gate terminal to allow an identical common input voltage to be input to the first gate terminal and the second gate terminal, and a CMOS output terminal connected to the common drain terminal to output a common output voltage.

The CMOS output terminal may output a maximum voltage with a preset magnitude when a voltage input to the CMOS input terminal is less than a first reference voltage, output an intermediate voltage with a preset magnitude when the voltage input to the CMOS input terminal is greater than or equal to a second reference voltage and less than a third reference voltage, and output no voltage when the voltage input to the CMOS input terminal is greater than or equal to a fourth reference voltage.

The ternary CMOS device may further include a lowermost oxide material layer stacked on a bottom of the two-dimensional material layer to be positioned on bottoms of the two-dimensional phase change material layer, the n-channel two-dimensional semiconductor material layer, and the p-channel two-dimensional semiconductor material layer.

According to an embodiment, a method of fabricating the ternary CMOS device includes depositing the two-dimensional material layer on a top of the lowermost oxide material layer, connecting the common drain terminal, the first source terminal, and the second source terminal to the top of the two-dimensional material layer, and connecting the first gate terminal and the second gate terminal to the top of the two-dimensional material layer.

The depositing of the two-dimensional material layer may include depositing the n-channel two-dimensional semiconductor material layer on the top of the lowermost oxide material layer, depositing the p-channel two-dimensional semiconductor material layer on the top of the lowermost oxide material layer, and depositing the two-dimensional phase change material layer on the top of the lowermost oxide material layer.

The connecting of the first gate terminal and the second gate terminal may include depositing the first oxide material layer on the top of the n-channel two-dimensional semiconductor material layer, depositing the second oxide material layer on the top of the p-channel two-dimensional semiconductor material layer, connecting the first gate terminal to the top of the first oxide material layer, and connecting the second gate terminal to the top of the second oxide material layer.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a diagram illustrating a ternary CMOS device according to an embodiment;

FIG. 2 is a diagram illustrating configurations of a ternary CMOS device according to an embodiment;

FIG. 3 is a diagram illustrating two-dimensional phase change materials;

FIG. 4 is a graph for describing a two-dimensional phase change material having a decreasing band gap with increasing thickness;

FIG. 5 is a graph for describing a two-dimensional phase change material having an increasing conductivity with increasing thickness;

FIG. 6 is a diagram illustrating three states implemented in a ternary inverter;

FIG. 7 is a diagram for describing a ternary device in which circuit complexity decreases with an increase in logic digits compared to the prior art;

FIG. 8 is a diagram for describing a simplification of an artificial neural network connection by the introduction of a ternary device;

FIG. 9 is a circuit diagram showing the characteristics of a ternary CMOS device according to an embodiment;

FIG. 10 is a graph showing a current flowing via a ternary CMOS device according to a voltage applied to the gate; and

FIG. 11 is a graph showing the input/output characteristics of a ternary CMOS device according to an embodiment.

### DETAILED DESCRIPTION OF EXEMPLARY EMBODIMENTS

Hereinafter, the feature of the present disclosure will be described in detail with reference to exemplary embodiments and accompanying drawings to clarify solutions of problems to be solved according to the present disclosure. In the following description, the same reference numerals will be assigned to the same components even though the components are illustrated in different drawings. In addition, when the description is made with reference to a present drawing, a component in another drawing may be cited if necessary.

Directional terms such as “upper side”, “lower side”, “one side”, and “other side” are used in relation to the orientations in the disclosed drawings. Since components of the embodiments of the present disclosure may be positioned in various orientations, the directional terms are merely illustrative and do not limit the components.

In addition, throughout the specification, unless explicitly described to the contrary, the word “comprise” and variations such as “comprises” or “comprising” will be understood to imply the inclusion of stated elements but not the exclusion of any other elements. In the above description, when a part is connected to the other part, the parts are not only directly connected to each other, but also indirectly connected to each other while interposing another part therebetween.

Terms such as first and second are used to distinguish one component from another component, and the components are not limited by the above-mentioned terms. As used herein, singular forms may include plural forms as well unless the context clearly indicates otherwise.

In each step, identification symbols are used for convenience of description and the identification symbols do not describe the order of the steps and the steps may be performed in a different order from the described order unless the context clearly indicates a specific order.

Hereinafter, embodiments of the present disclosure will be described in detail with reference to the exemplary drawings. The embodiments of the present disclosure may be modified in various forms, and the scope of the present disclosure should not be construed as being limited to the embodiments below. The present embodiments are provided to more completely explain the present disclosure to those with average knowledge in the art. Therefore, the shapes of the elements in the drawings are exaggerated to emphasize a clearer explanation.

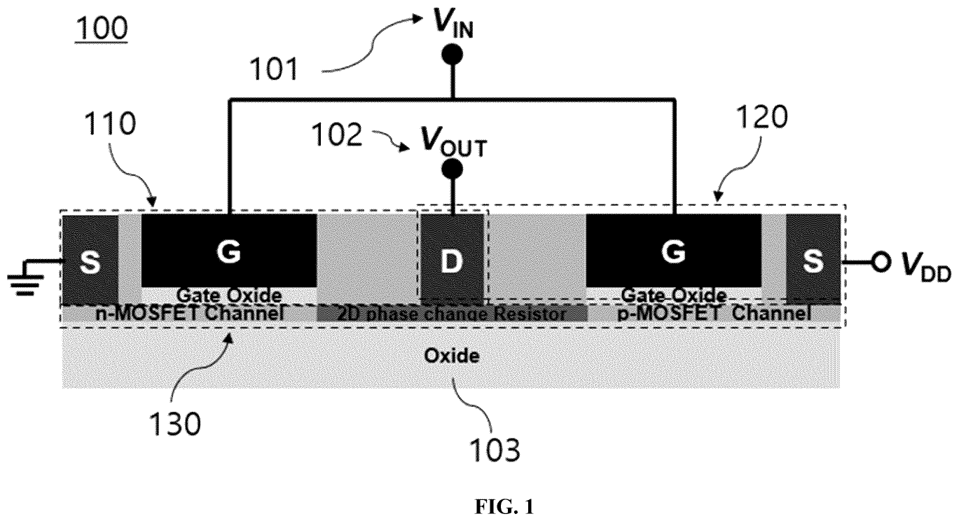

FIG. 1 is a diagram illustrating a ternary CMOS device according to an embodiment.

Referring to FIG. 1, a ternary MOSFET device 100 may be composed of an n-type MOSFET region 110, a p-type MOSFET region 120, and a two-dimensional material layer 130.

The ternary CMOS device 100 may be a CMOS device capable of performing a ternary operation, unlike a conventional CMOS device that generally performs a binary operation.

The two-dimensional material layer 130 may be formed of a two-dimensional material. The configurations of the n-type MOSFET region 110 may be stacked on top of the two-dimensional material layer 130. The configurations of the p-type MOSFET region 120 may be stacked on top of the two-dimensional material layer 130.

The n-type MOSFET region 110 may be a region having similar properties to a conventional n-MOSFET, and the p-type MOSFET region 120 may be a region having similar properties to a conventional p-MOSFET. However, the n-type MOSFET region 110 and the p-type MOSFET region 120 may be driven similarly to a conventional n-MOSFET and a conventional p-MOSFET, respectively, but may not be driven completely identically.

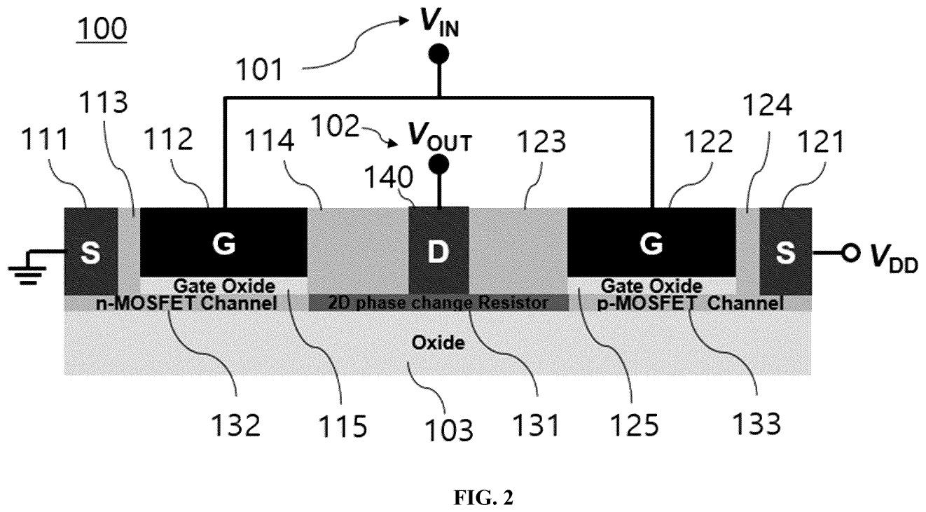

FIG. 2 is a diagram illustrating configurations of a ternary CMOS device according to an embodiment.

Referring to FIGS. 1 and 2, the two-dimensional material layer 130 may include a two-dimensional phase change material layer 131, an n-channel two-dimensional semiconductor material layer 132, and a p-channel two-dimensional semiconductor material layer 133.

The two-dimensional phase change material layer 131 may be formed of a two-dimensional phase change material.

The two-dimensional phase change material may be a material that allows a MOSFET device having the two-dimensional phase change material as a channel to allow a constant current to flow regardless of an input voltage applied to the gate.

The n-channel two-dimensional semiconductor material layer 132 may be stacked on the bottom of the n-type MOSFET region 110. The n-channel two-dimensional semiconductor material layer 132 may be connected to one end of the two-dimensional phase change material layer 131.

The p-channel two-dimensional semiconductor material layer 133 may be stacked on the bottom of the p-type MOSFET region 120. The p-channel two-dimensional semiconductor material layer 133 may be connected to the other terminal of the two-dimensional phase change material layer 131.

The two-dimensional semiconductor material layer may be formed of a two-dimensional semiconductor material that has the property of changing into a conductor by a voltage change without separate doping.

The two-dimensional semiconductor material is transition-metal dicalcogenides (TMDCs), which have a layered structure with one transition metal atom and two chalcogen atoms, and may be either single or multiple layers of crystalline material with atomic layers.

The two-dimensional semiconductor material has an insulator characteristic under normal conditions, but may show a characteristic of changing into a conductor when an electric field is applied. In other words, the two-dimensional semiconductor material may be a material that has a specific polarity only by a voltage change without separate doping.

The n-channel two-dimensional semiconductor material layer 132 may be formed of a two-dimensional semiconductor material that has a characteristic of changing into an n-type conductor by a voltage change without separate doping.

The p-channel two-dimensional semiconductor material layer 133 may be formed of a two-dimensional semiconductor material that has a characteristic of changing into a p-type conductor by a voltage change without separate doping.

The n-channel two-dimensional semiconductor material layer 132 may be an n-channel of CMOS. In this case, the n-channel two-dimensional semiconductor material layer 132 may be made of MoS₂, but is not limited thereto and it may be possible that various materials capable of forming an n-channel among two-dimensional semiconductor materials are used.

The p-channel two-dimensional semiconductor material layer 133 may be a p-channel of CMOS. In this case, the p-channel two-dimensional semiconductor material layer 133 may be made of WSe₂, but is not limited thereto, and it may be possible that various materials capable of forming a p-channel among two-dimensional semiconductor materials are used.

Referring to FIGS. 1 and 2, the n-type MOSFET region 110 may include a first source terminal 111, a first gate terminal 112, a first spacer 113, a second spacer 114, a first oxide material layer 115, and a common drain terminal 140.

The n-type MOSFET region 110 may include the first source terminal 111, the first gate terminal 112, the first spacer 113, the second spacer 114, the first oxide material layer 115, and the common drain terminal 140.

The p-type MOSFET region 120 may include a second source terminal 121, a second gate terminal 122, a third spacer 123, a fourth spacer 124, a second oxide material layer 125, and the common drain terminal 140.

The first source terminal 111 may be stacked on the top of the n-channel two-dimensional semiconductor material layer 132. The first source terminal 111 may be electrically connected to ground.

The first gate terminal 112 may be stacked on the top of the n-channel two-dimensional semiconductor material layer 132. The first gate terminal 112 may be configured to receive an input voltage V_{IN}.

The common drain terminal 140 may be stacked on the top of the two-dimensional phase change material layer 131.

The second source terminal 121 may be stacked on the top of the p-channel two-dimensional semiconductor material layer 133. The second source terminal 121 may be applied with a power supply voltage V_{DD}.

The second gate terminal 122 may be stacked on the top of the p-channel two-dimensional semiconductor material layer 133. The second gate terminal 122 may be configured to receive the same input voltage V_{IN} as the input voltage received by the first gate terminal 112.

A CMOS input terminal 101 may be configured to be connected to the first gate terminal 112 and the second gate terminal 122 such that the same common input voltage V_{IN} is input to the first gate terminal 112 and the second gate terminal 122. A CMOS output terminal 102 may be connected to the common drain terminal 140 to output a common output voltage V_{OUT}.

The common drain terminal 140, the first source terminal 111, and the second source terminal 121 may be formed by depositing metal through a deposition technique such as an E-beam evaporator after patterning is performed through an exposure process.

The two-dimensional phase change material layer 131 may be configured to act as a resistor to limit the flow of current regardless of the magnitude of the input voltage VIN applied to the first gate terminal 112 and the second gate terminal 122. Specifically, the two-dimensional phase change material layer 131 may act as a resistor to limit an on current flowing via the n-type MOSFET region 110, the n-channel two-dimensional semiconductor material layer 132, the p-type MOSFET region 120, and the p-channel two-dimensional semiconductor material layer 133.

The first oxide material layer 115 may be stacked on the top of the n-channel two-dimensional semiconductor material layer 132 and the bottom of the first gate terminal 112 such that the first oxide material layer 115 is positioned between the n-channel two-dimensional semiconductor material layer 132 and the first gate terminal 112.

The first oxide material layer 115 may serve to electrically isolate the n-channel two-dimensional semiconductor material layer 132 and the first gate terminal 112.

The second oxide material layer 125 may be stacked on the top of the p-channel two-dimensional semiconductor material layer 133 and the bottom of the second gate terminal 122 such that the second oxide material layer 125 is positioned between the p-channel two-dimensional semiconductor material layer 133 and the second gate terminal 122.

The second oxide material layer 125 may serve to electrically isolate the p-channel two-dimensional semiconductor material layer 133 and the second gate terminal 122.

The first oxide material layer 115, the second oxide material layer 125, and the lowermost oxide material layer 103 may be formed of a high-k material with a large dielectric constant (e.g., Al₂O₃ or HfO₂). The first oxide material layer 115 and the second oxide material layer 125 may be formed by deposition via Atomic Layer Deposition (ALD), but are not limited thereto.

The first spacer 113 may include an insulating material. The first spacer 113 may be stacked on top of the n-channel two-dimensional semiconductor material layer 132 and may be arranged between the first gate terminal 112 and the first source terminal 111 and between the first oxide material layer 115 and the first source terminal 111.

The second spacer 114 may include an insulating material. The second spacer 114 may be stacked on top of the two-dimensional phase change material layer 131 and may be arranged between the first gate terminal 112 and the common drain terminal 140 and between the first oxide material layer 115 and the common drain terminal 140.

The third spacer 123 may include an insulating material. The third spacer 123 may be stacked on top of the two-dimensional phase change material layer 131 and may be arranged between the second gate terminal 122 and the common drain terminal 140 and between the second oxide material layer 125 and the common drain terminal 140.

The fourth spacer 124 may include an insulating material. The fourth spacer 124 may be stacked on top of the p-channel two-dimensional semiconductor material layer 133 and arranged between the second gate terminal 122 and the second source terminal 121 and between the second oxide material layer 125 and the second source terminal 121.

The ternary CMOS device 100 may include the lowermost oxide material layer 103.

The lowermost oxide material layer 103 may be stacked on the bottom of the two-dimensional material layer 130 such that the lowermost oxide material layer 103 is positioned on the bottom of the two-dimensional phase change material layer 131, the n-channel two-dimensional semiconductor material layer 132, and the p-channel two-dimensional semiconductor material layer 133.

A method of fabricating the ternary CMOS device 100 described above may include depositing the two-dimensional material layer 130 on top of the lowermost oxide material layer 103, connecting the common drain terminal 140, the first source terminal 111, and the second source terminal 121 to the top of the two-dimensional material layer 130, and connecting the first gate terminal 112 and the second gate terminal 122 to the top of the two-dimensional material layer 130.

The depositing of the two-dimensional material layer 130 may include depositing the n-channel two-dimensional semiconductor material layer 132 on the top of the lowermost oxide material layer 103, depositing the p-channel two-dimensional semiconductor material layer 133 on the top of the lowermost oxide material layer 103, and depositing the two-dimensional phase change material layer 131 on the top of the lowermost oxide material layer 103.

The connecting of the first gate terminal 112 and the second gate terminal 122 may include depositing the first oxide material layer 115 on the top of the n-channel two-dimensional semiconductor material layer 132, depositing the second oxide material layer 125 on the top of the p-channel two-dimensional semiconductor material layer 133, connecting the first gate terminal 112 to the top of the first oxide material layer 115, and connecting the second gate terminal 122 to the top of the second oxide material layer 125.

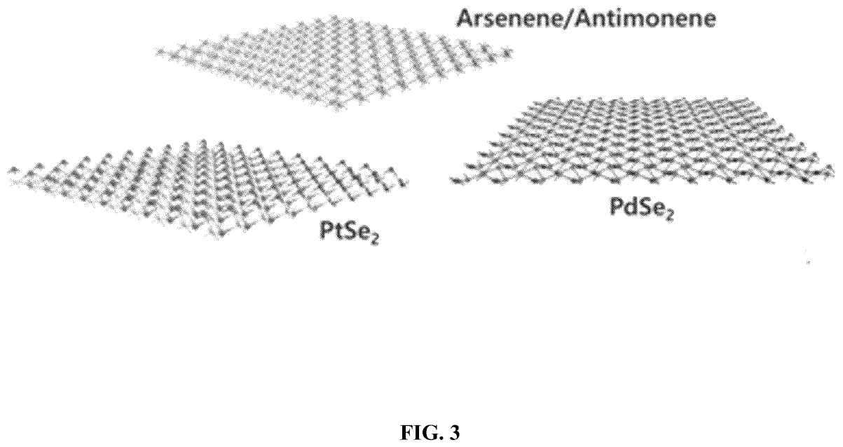

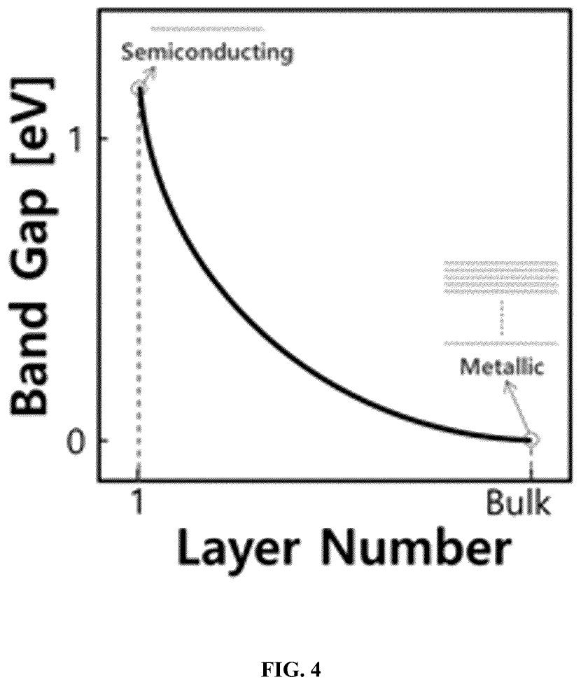

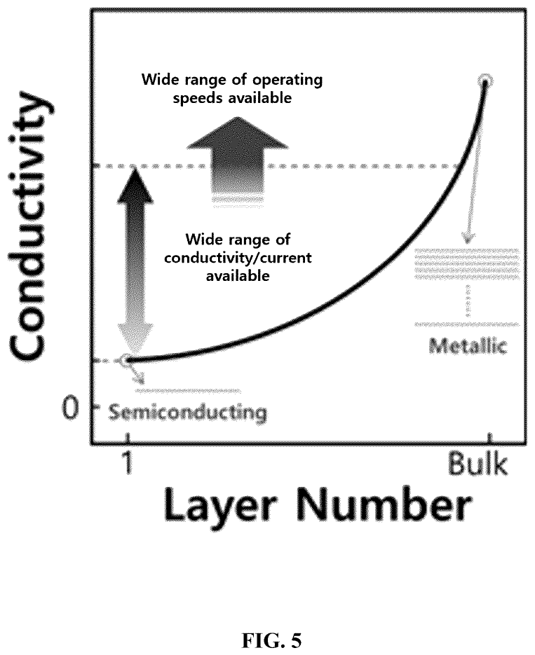

FIG. 3 is a diagram illustrating two-dimensional phase change materials, FIG. 4 is a graph for describing a two-dimensional phase change material having a decreasing band gap with increasing thickness, and FIG. 5 is a graph for describing a two-dimensional phase change material having an increasing conductivity with increasing thickness.

Referring to FIGS. 3, 4, and 5, the two-dimensional phase change material layer 131 may be formed of a two-dimensional phase change material having a decreasing band gap as the thickness of the layer increases.

The two-dimensional phase change material layer may be formed of a two-dimensional material that exhibits a phase transition from a semiconductor to a conductor as a 2D phase transition channel as illustrated in FIG. 3 with a change in thickness.

The two-dimensional phase change material layer 131 may be formed of Transition Metal Dichalcogenides (TMDs) having a decreasing band gap as the thickness of the layer increases. However, the two-dimensional phase change material is not necessarily limited to transition metal chalcogenides.

The two-dimensional phase change material layer 131 may be formed of at least one of the aforementioned chalcogenides, Platinum Diselenide (PtSe₂) and Palladium Diselenide (PdSe₂). However, the two-dimensional phase change material is not limited to the aforementioned materials.

For example, the two-dimensional phase change material layer 131 may be arsenene which is a two-dimensional phase change material composed of single atoms, is an allotrope of arsenic (As) and has a two-dimensional structure. Furthermore, the two-dimensional phase change material layer 131 may be antimonene which is a two-dimensional phase change material composed of single atoms, is an allotrope of antimony (Sb), and has a two-dimensional structure.

The two-dimensional phase change materials such as PdSe₂, PtSe₂, arsenene, and antimonene have a band gap of more than 1 eV in the monolayer, as shown in FIG. 4, exhibiting semiconducting property, but as the thickness increases, the band gap decreases and becomes zero, showing a phase transition phenomenon of exhibiting metallic property.

By utilizing the phase change properties with a change in thickness in the two-dimensional phase change material as described above, it is possible to secure a wide range of conductivity and current by controlling the thickness, as shown in FIG. 5, enabling a wide range of operating speeds with the same device structure and process method, enabling T-CMOS technology with a wide range of applications from ultra-low power to high performance.

In addition, two-dimensional phase change materials may be grown at low temperatures and be semiconductor materials capable of enabling top integration under process conditions that do not deteriorate the Si CMOS properties and reliability, resulting in promising materials for monolithic 3D integration technology, which may further improve the integration of devices.

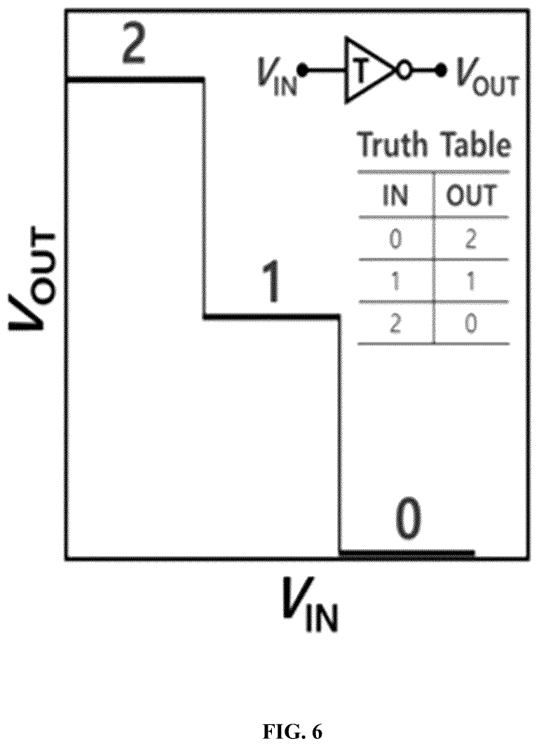

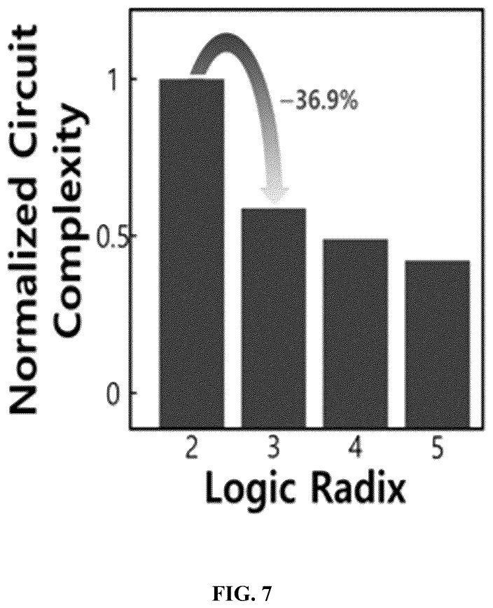

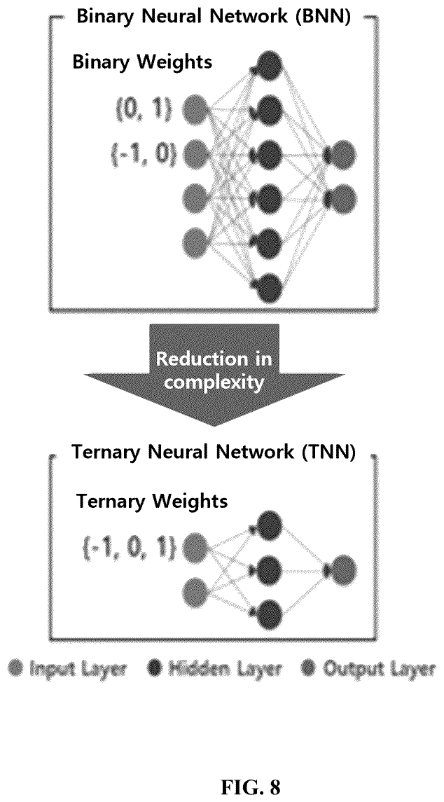

FIG. 6 is a diagram illustrating three states implemented in a ternary inverter, FIG. 7 is a diagram for describing a ternary device in which circuit complexity decreases with an increase in logic digits compared to the prior art, and FIG. 8 is a diagram for describing a simplification of an artificial neural network connection by the introduction of a ternary device.

Referring to FIGS. 6, 7, and 8, the advantages of devices that utilize ternary operations over devices that utilize traditional binary operations may be seen.

The ternary device shown in FIG. 6 represents information as a ternary series of 0s, 1s, and 2s, which may dramatically improve power consumption by reducing the amount of information that needs to be processed compared to traditional binary devices.

By switching the representation of information from bits in binary devices to trits in ternary devices, the voltage required for the state transition in FIG. 6 is half that of a conventional binary, and 2 bits may be represented by 1 trit, which dramatically reduces the circuit complexity, as shown in FIG. 7, enabling a dramatic reduction in power consumption.

Also, in the implementation of artificial neural networks, which has been actively researched in recent years, the introduction of ternary weights {−1, 0, 1} instead of the conventional binary weights {0, 1}, as shown in FIG. 8, may simplify circuit connections and reduce power consumption.

The implementation of the Ternary Inverter (T-Inverter) shown in FIG. 6 is needed for representing information in ternary with these advantages. In the past, various studies have been conducted to distribute a drive voltage V_{DD} to form the intermediate state V_{DD}/2, but this approach has many problems.

For example, a technique of using the stepped current-voltage characteristic due to multiple threshold voltages in the on-state of the device by forming a quantum dot (QD) on the gate oxide in Si MOSFET to implement multiple threshold voltages by resonant tunneling from the Si channel to the QD is difficult to implement a stable constant current due to the scattering of threshold voltage caused by uneven QD formation. This has the problem that a constant current is formed in the ON state of the device, resulting in very large static power consumption in the additional state. In addition, it is difficult to reduce power consumption by scaling an operating voltage (V_{DD}) due to the implementation of multiple threshold voltages.

The technology using the negative differential resistance of the on-state of the device, which is implemented at the level of small flakes obtained by mechanical peeling technique by utilizing the negative differential resistance by tunneling in a two-dimensional material heterojunction structure, has the problem that the static power consumption in the additional state is very large due to the formation of a constant current in the on-state of the device. Also, the implementation of multiple threshold voltages makes it difficult to reduce power consumption by operating voltage (V_{DD}) scaling.

A technology that uses a stepped current-voltage characteristic due to multiple threshold voltages in the ON state of a device by implementing multiple threshold voltages based on the Mobility Edge Quantisation Effect principle using ZnO composites has the problem that a static current is formed in the ON state of the device and the static power consumption is very large in the additional state. Also, the implementation of multiple threshold voltages makes it difficult to reduce power consumption by operating voltage (V_{DD}) scaling.

The technology of utilizing the constant current in the OFF state of the device by forming a local PN junction at the bottom of a channel in Si MOSFET to implement a small constant current component by tunneling independent of a gate voltage has the problem that it is only suitable for ultra-low power applications because it utilizes a small constant current in the OFF state of the device. Therefore, it may be desirable to implement a CMOS device capable of ternary operation in a new way.

The existing Ternary CMOS (T-CMOS) device has a clear limitation in its application range, but the illustrated ternary CMOS device 100 supports a wide range of operating speeds and may be utilized for a variety of purposes from ultra-low power to high performance.

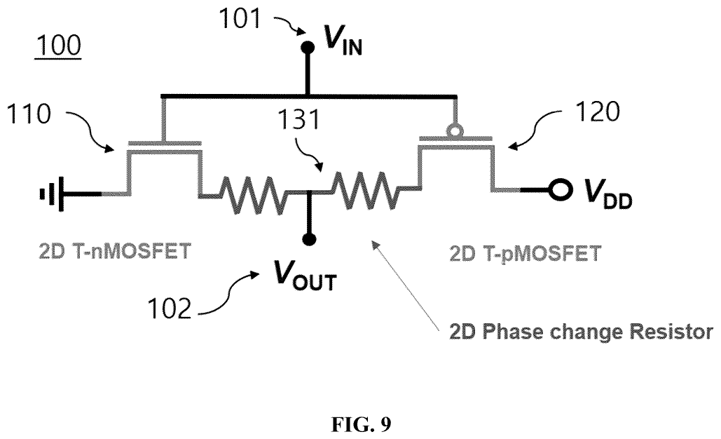

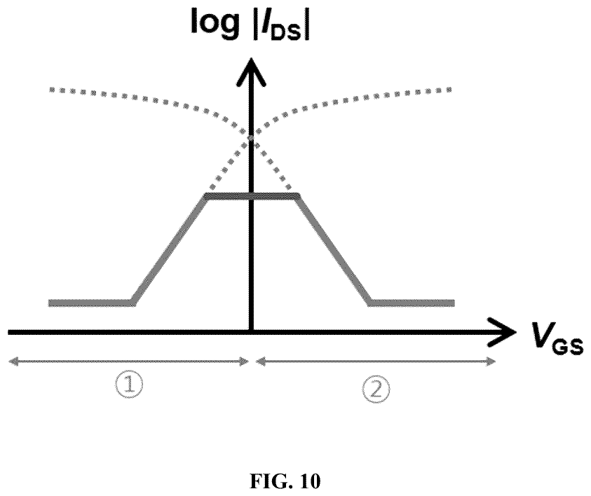

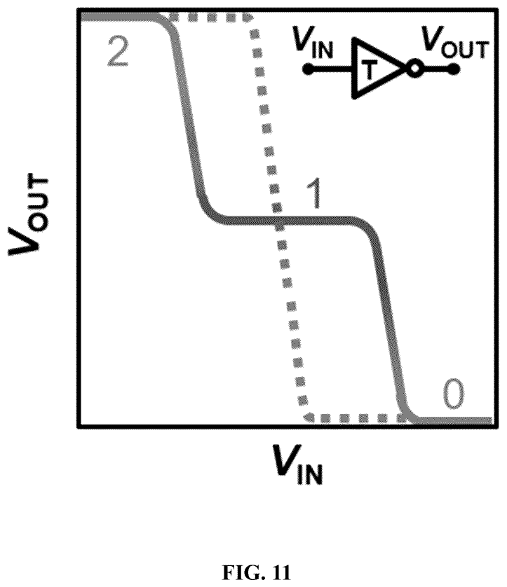

FIG. 9 is a circuit diagram showing the characteristics of a ternary CMOS device according to an embodiment, FIG. 10 is a graph showing a current flowing via a ternary CMOS device according to a voltage applied to the gate, and FIG. 11 is a graph showing the input/output characteristics of a ternary CMOS device according to an embodiment.

Referring to FIGS. 9, 10, and 11, as can be seen from the illustrated I_{DS}-V_{GS} characteristics, the two-dimensional phase change material layer 131 acts as a resistor and limits the On current of an n/p MOSFET, so that the current cannot increase beyond a certain level of constant current even when the MOSFET is turned on, and as illustrated, the ternary CMOS device 100, that is, the T-CMOS Inverter may generate an intermediate state.

The ternary CMOS device 100 may utilize a constant current in the On state of the device to implement a ternary intermediate state. In this case, the constant current utilized may not be a current due to tunneling in Si-based junction, but may be a current flowing via the Schottky junction of the Source/Drain metal and the undoped two-dimensional material. The ternary CMOS device 100 according to an embodiment is able to implement a constant current more robustly and stably because there is no process dispersion due to doping.

Referring to the I_{DS}-V_{GS} curve illustrated in FIG. 10, it may be seen that \textcircled{1} in the negative gate voltage range, as the gate source voltage V_{GS} increases, the current flows via the n-channel two-dimensional semiconductor material layer 132, and at a certain point, the I_{DS} stops increasing and becomes saturated.

Also, it may be seen that \textcircled{2} in the positive gate voltage range, as the gate source voltage V_{GS} decreases, the current flows via the p-channel two-dimensional semiconductor material layer 133, and at a certain point, the I_{DS} stops increasing and becomes saturated.

Referring to FIG. 11, the input/output characteristics of the ternary CMOS device 100 according to an embodiment may be seen.

When a voltage input to the CMOS input terminal 101 is less than a first reference voltage, the CMOS output terminal 102 may output a maximum voltage with a certain magnitude.

When the voltage input to the CMOS input terminal 101 is equal to or greater than a second reference voltage and less than a third reference voltage, the CMOS output terminal 102 may output an intermediate voltage with a certain magnitude.

Unlike conventional T-CMOS studies using tunneling current, the ternary CMOS device 100 according to an embodiment may be a ternary device in which a two-dimensional phase change channel below the common drain to which the output voltage is connected acts as a resistor to limit the On-current of each MOSFET.

When the voltage input to the CMOS input terminal 101 is equal to or greater than a fourth reference voltage, the CMOS output terminal 102 may be configured such that no voltage is output.

The above description illustrates the disclosure. Embodiments of the disclosure are described above, and the disclosure may be used in other various combinations and alterations of the embodiments, and environments. The disclosure may be changed or modified within a range equivalent to what is described above and/or a range of technologies or knowledge of ordinary skill in the art. The aforementioned embodiments of the disclosure are for explaining the best modes to practice the technical idea of the disclosure, and many different modifications thereto may be made for a specific application area and usage. Accordingly, the embodiments of the disclosure are not intended to limit the scope of the disclosure to what are disclosed above. The appended claims are to be interpreted as including other embodiments.

According to an aspect of the present disclosure, it is possible to performing ternary operations.

In addition, according to another aspect of the present disclosure, it is possible to provide a ternary CMOS device available for various purposes from an ultra-low power environment to a high-performance environment by supporting a wide range of operating speeds.

In addition, according to another aspect of the present disclosure, it is possible to provide a ternary CMOS device capable of being implemented more robustly and stably without the process dispersion due to doping.

In addition, according to another aspect of the present disclosure, it is possible to provide a ternary CMOS device capable of using a semiconductor material capable of enabling top integration under process conditions that do not deteriorate the characteristics and reliability of Si-based CMOS to increase the integration density of a device.

Meanwhile, the effects obtainable from the present disclosure are not limited to the aforementioned effects, and any other effects not mentioned herein will be clearly understood from the following description by those skilled in the art to which the present disclosure pertains.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A ternary CMOS device comprising:
a two-dimensional material layer formed of a two-dimensional material;
an n-type MOSFET region stacked on a top of the two-dimensional material layer; and
a p-type MOSFET region stacked on the top of the two-dimensional material layer, and
wherein the two-dimensional material layer includes:
a two-dimensional phase change material layer formed of a two-dimensional phase change material;
an n-channel two-dimensional semiconductor material layer stacked on a bottom of the n-type MOSFET region and connected to one end of the two-dimensional phase change material layer; and
a p-channel two-dimensional semiconductor material layer stacked on a bottom of the p-type MOSFET region and connected to the other end of the two-dimensional phase change material layer.

2. The ternary CMOS device of claim 1, wherein the n-channel two-dimensional semiconductor material layer is formed of a two-dimensional semiconductor material having a characteristic of changing into an n-type conductor by a voltage change without separate doping, and
wherein the p-channel two-dimensional semiconductor material layer is formed of a two-dimensional semiconductor material having a characteristic of changing into a p-type conductor by a voltage change without separate doping.

3. The Ternary CMOS device of claim 1, wherein the two-dimensional phase change material layer is formed of a two-dimensional phase change material having a decreasing band gap as a thickness of the layer increases.

4. The ternary CMOS device of claim 3, wherein the two-dimensional phase change material layer is formed of transition metal dichalcogenides (TMDs) having a decreasing band gap as the thickness of the layer increases.

5. The ternary CMOS device of claim 3, wherein the two-dimensional phase change material layer is formed of at least one of PtSe₂ (Platinum Diselenide) and PdSe₂ (Palladium Diselenide).

6. The ternary CMOS device of claim 3, wherein the two-dimensional phase change material layer is formed of at least one of arsenene which is a two-dimensional phase change material composed of single atoms, is an allotrope of arsenic (As) and has a two-dimensional structure, and antimonene which is a two-dimensional phase change material composed of single atoms, is an allotrope of antimony (Sb) and has a two-dimensional structure.

7. The ternary CMOS device of claim 1, wherein the n-type MOSFET region includes:
a first source terminal stacked on a top of the n-channel two-dimensional semiconductor material layer;
a first gate terminal stacked on the top of the n-channel two-dimensional semiconductor material layer to receive an input voltage; and
a common drain terminal stacked on a top of the two-dimensional phase change material layer, and
wherein the p-type MOSFET region includes:
a second source terminal stacked on a top of the p-channel two-dimensional semiconductor material layer;
a second gate terminal stacked on the top of the p-channel two-dimensional semiconductor material layer to receive the input voltage; and
the common drain terminal.

8. The ternary CMOS device of claim 7, wherein the two-dimensional material layer is configured to act as a resistor to limit an on current flowing via the n-type MOSFET region, the n-channel two-dimensional semiconductor material layer, the p-type MOSFET region, and the p-channel two-dimensional semiconductor material layer.

9. The ternary CMOS device of claim 7, wherein the n-type MOSFET region further includes a first oxide material layer stacked on the top of the n-channel two-dimensional semiconductor material layer and a bottom of the first gate terminal to be positioned between the n-channel two-dimensional semiconductor material layer and the first gate terminal, and
wherein the p-type MOSFET region further includes a second oxide material layer stacked on the top of the p-channel two-dimensional semiconductor material layer and a bottom of the second gate terminal to be positioned between the p-channel two-dimensional semiconductor material layer and the second gate terminal.

10. The ternary CMOS device of claim 9, further comprising:
a first spacer formed of an insulating material and stacked on the top of the n-channel two-dimensional semiconductor material layer and arranged between the first gate terminal and the first source terminal and between the first oxide material layer and the first source terminal;
a second spacer formed of an insulating material and stacked on the top of the two-dimensional phase change material layer and arranged between the first gate terminal and the common drain terminal and between the first oxide material layer and the common drain terminal;
a third spacer formed of an insulating material and stacked on the top of the two-dimensional phase change material layer and arranged between the second gate terminal and the common drain terminal and between the second oxide material layer and the common drain terminal; and
a fourth spacer formed of an insulating material and stacked on the top of the p-channel two-dimensional semiconductor material layer and arranged between the second gate terminal and the second source terminal and between the second oxide material layer and the second source terminal.

11. The ternary CMOS device of claim 7, further comprising:
a CMOS input terminal connected to the first gate terminal and the second gate terminal to allow an identical common input voltage to be input to the first gate terminal and the second gate terminal; and
a CMOS output terminal connected to the common drain terminal to output a common output voltage.

12. The ternary CMOS device of claim 11, wherein the CMOS output terminal is configured to:
output a maximum voltage with a preset magnitude when a voltage input to the CMOS input terminal is less than a first reference voltage;
output an intermediate voltage with a preset magnitude when the voltage input to the CMOS input terminal is greater than or equal to a second reference voltage and less than a third reference voltage; and
output no voltage when the voltage input to the CMOS input terminal is greater than or equal to a fourth reference voltage.

13. The ternary CMOS device of claim 9, further comprising:
a lowermost oxide material layer stacked on a bottom of the two-dimensional material layer to be positioned on bottoms of the two-dimensional phase change material layer, the n-channel two-dimensional semiconductor material layer, and the p-channel two-dimensional semiconductor material layer.

14. A method of fabricating the ternary CMOS device of claim 13, the method comprising:
depositing the two-dimensional material layer on a top of the lowermost oxide material layer;
connecting the common drain terminal, the first source terminal, and the second source terminal to the top of the two-dimensional material layer; and
connecting the first gate terminal and the second gate terminal to the top of the two-dimensional material layer.

15. The method of claim 14, wherein the depositing of the two-dimensional material layer includes:
depositing the n-channel two-dimensional semiconductor material layer on the top of the lowermost oxide material layer;
depositing the p-channel two-dimensional semiconductor material layer on the top of the lowermost oxide material layer; and
depositing the two-dimensional phase change material layer on the top of the lowermost oxide material layer.

16. The method of claim 15, wherein the connecting of the first gate terminal and the second gate terminal includes:
depositing the first oxide material layer on the top of the n-channel two-dimensional semiconductor material layer;
depositing the second oxide material layer on the top of the p-channel two-dimensional semiconductor material layer;
connecting the first gate terminal to the top of the first oxide material layer, and
connecting the second gate terminal to the top of the second oxide material layer.
